(19) United States
(12) Patent Application Publication
(10) Pub. No.: US 2017/0111051 A1
(43) Pub. Date: Apr. 20, 2017

(54) FREQUENCY GENERATING CIRCUIT USING QUARTZ CRYSTAL RESONATOR

(71) Applicant: Ping-Ying WANG, Hsinchu City (TW)

(72) Inventor: Ping-Ying WANG, Hsinchu City (TW)

(21) Appl. No.: 15/293,865

(22) Filed: Oct. 14, 2016

Related U.S. Application Data
(60) Provisional application No. 62/241,504, filed on Oct. 14, 2015.

(51) Int. Cl. H03L 7/087; H03L 7/099; H03H 9/19

(52) U.S. Cl. CPC H03L 7/087; H03H 9/19; H03L 7/099

(57) ABSTRACT

A frequency generating circuit includes: a differential delay circuit arranged to operably delay an input signal to generate a first delayed signal and a second delayed signal; a quartz crystal resonator arranged to operably conduct a band-pass filtering operation on one of the first and second delayed signals to generate a frequency signal; a compensation capacitor, coupled between another output of the differential delay circuit and an output of the quartz crystal resonator, arranged to operably suppress noise in the frequency signal; an oscillator arranged to operably generate an oscillating signal under control of a control signal; a frequency divider arranged to operably conduct a frequency-dividing operation on the oscillating signal to generate the input signal; and a feedback control circuit arranged to operably generate the control signal according to the frequency signal.

### CROSS-REFERENCE TO RELATED APPLICATIONS

This application claims the benefit of priority to U.S. Provisional Application Ser. No. 62/241,504, filed on Oct. 14, 2015; the entirety of which is incorporated herein by reference for all purposes.

### BACKGROUND

The disclosure generally relates to a frequency generating circuit and, more particularly, to a frequency generating circuit using a quartz crystal resonator as a band-pass filter.

A quartz crystal resonator is widely used in many frequency generating devices, such as the Pierce oscillator, due to its simple architecture and low cost merits. As is well known in related art, the noise level of the signal generated by the quartz crystal resonator can be reduced by increasing the current injected into the quartz crystal resonator. However, the increasing of the current injected into the quartz crystal resonator accelerates aging of the quartz crystal resonator, thereby reducing the reliability of the quartz crystal resonator. Namely, there is a trade-off between the reliability of the quartz crystal resonator and the noise level of the signal generated by the quartz crystal resonator. The above trade-off property limits the applicable fields of the quartz crystal resonator. For example, it is difficult to apply the quartz crystal resonator in many applications demanding low power consumption.

In addition, the pulling range (i.e., the frequency adjustable range or frequency tuning range) of the conventional frequency generating device is severely restricted by the parasitic capacitance of the quartz crystal resonator. Accordingly, the pulling range of the quartz crystal resonator is highly depending upon the material of the quartz crystal resonator. As a result, the conventional frequency generating device requires utilizing high-end quartz crystal resonators in order to meet the wide pulling range requirement. In this situation, the overall hardware cost of the conventional frequency generating device is inevitably increased.

### SUMMARY

An example embodiment of a frequency generating circuit is disclosed, comprising: a differential delay circuit, arranged to operably delay an input signal to generate a pair of differential delayed signals, wherein the pair of differential delayed signals includes a first delayed signal and a second delayed signal; a quartz crystal resonator, coupled with one output of the differential delay circuit, arranged to operably conduct a band-pass filtering operation on one of the first and second delayed signals to generate a frequency signal; a compensation capacitor, coupled between another output of the differential delay circuit and an output of the quartz crystal resonator, arranged to operably suppress noise in the frequency signal; an oscillator arranged to operably generate an oscillating signal under control of a control signal; a frequency divider, coupled with the oscillator and the differential delay circuit, arranged to operably conduct a frequency-dividing operation on the oscillating signal to generate the input signal; and a feedback control circuit, coupled with the output of the quartz crystal resonator and an input of the oscillator, arranged to operably generate the control signal according to the frequency signal.

Another example embodiment of a frequency generating circuit is disclosed, comprising: a differential delay circuit, arranged to operably delay an input signal to generate a pair of differential delayed signals, wherein the pair of differential delayed signals includes a first delayed signal and a second delayed signal; a quartz crystal resonator, coupled with one output of the differential delay circuit, arranged to operably conduct a band-pass filtering operation on one of the first and second delayed signals to generate a frequency signal; a compensation capacitor, coupled between another output of the differential delay circuit and an output of the quartz crystal resonator, arranged to operably suppress noise in the frequency signal; an oscillator, coupled with the differential delay circuit, arranged to operably generate an oscillating signal to be the input signal under control of a control signal; and a feedback control circuit, coupled with the output of the quartz crystal resonator and an input of the oscillator, arranged to operably generate the control signal according to the frequency signal.

Another example embodiment of a frequency generating circuit is disclosed, comprising: a differential delay circuit, arranged to operably delay an input signal to generate a pair of differential delayed signals, wherein the pair of differential delayed signals includes a first delayed signal and a second delayed signal; a quartz crystal resonator, coupled with one output of the differential delay circuit, arranged to operably conduct a band-pass filtering operation on one of the first and second delayed signals to generate a frequency signal; and a compensation capacitor, coupled between another output of the differential delay circuit and an output of the quartz crystal resonator, arranged to operably suppress noise in the frequency signal.

Both the foregoing general description and the following detailed description are examples and explanatory only, and are not restrictive of the invention as claimed.

### BRIEF DESCRIPTION OF THE DRAWINGS

FIG. 1 shows a simplified functional block diagram of a frequency generating circuit according to a first embodiment of the present disclosure.

FIG. 2 shows a simplified functional block diagram of the feedback control circuit in FIG. 1 according to a first embodiment of the present disclosure.

FIG. 3 shows a simplified functional block diagram of the feedback control circuit in FIG. 1 according to a second embodiment of the present disclosure.

FIG. 4 shows a simplified functional block diagram of the feedback control circuit in FIG. 1 according to a third embodiment of the present disclosure.

FIG. 5 shows a simplified functional block diagram of a frequency generating circuit according to a second embodiment of the present disclosure.

### DETAILED DESCRIPTION

Reference is made in detail to embodiments of the invention, which are illustrated in the accompanying drawings. The same reference numbers may be used throughout the drawings to refer to the same or like parts, components, or operations.

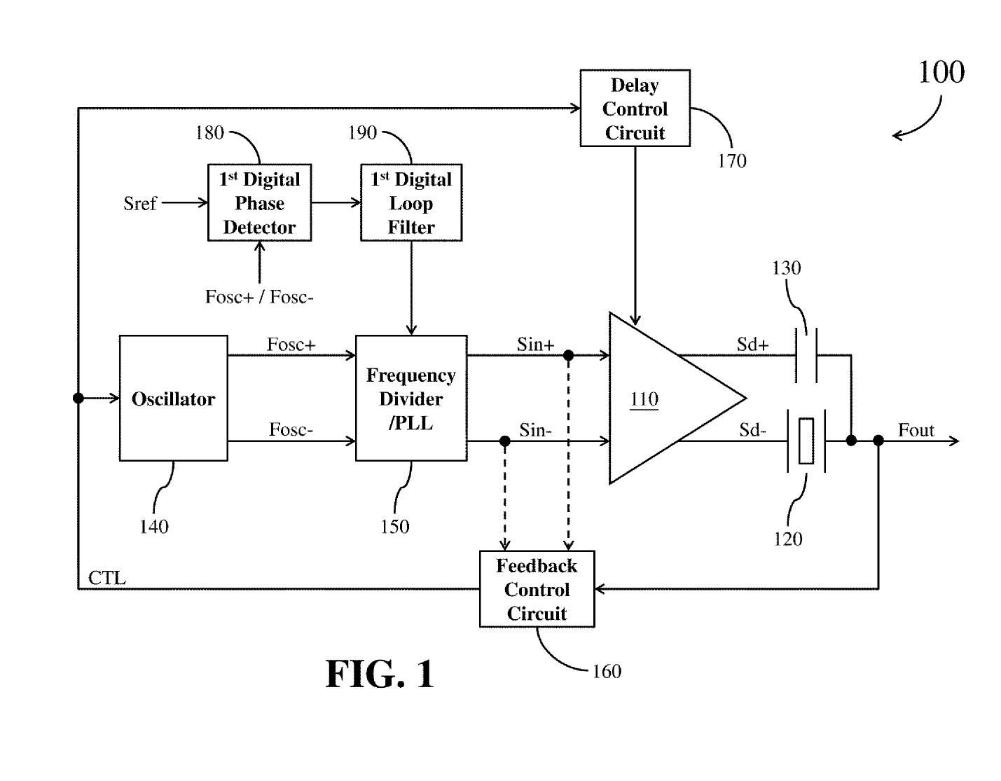

FIG. 1 shows a simplified functional block diagram of a frequency generating circuit 100 according to a first embodiment of the present disclosure. The frequency generating circuit 100 of this embodiment comprises a differential delay circuit 110, a quartz crystal resonator 120, a compensation capacitor 130, an oscillator 140, a frequency divider 150, a feedback control circuit 160, a delay control circuit 170, a first digital phase detector 180, and a first digital loop filter 190.

The differential delay circuit 110 is arranged to operably delay an input signal to generate a pair of differential delayed signals, wherein the pair of differential delayed signals includes a first delayed signal Sd+ and a second delayed signal Sd− which have a 180-degree phase difference with respect to each other. Accordingly, the first delayed signal Sd+ and the second delayed signal Sd− each has a phase difference with respect to the input signal of the differential delay circuit 110.

The quartz crystal resonator 120 is coupled with one output of the differential delay circuit 110 to receive either the first delayed signal Sd+ or the second delayed signal Sd−. In the frequency generating circuit 100, the quartz crystal resonator 120 is utilized to be a band-pass filter and arranged to operably conduct a band-pass filtering operation on either the first delayed signal Sd+ or the second delayed signal Sd− to generate a frequency signal Fout. The frequency of the frequency signal Fout is determined by the phase difference between the output signal (i.e., the frequency signal Fout) of the quartz crystal resonator 120 and the input signal (i.e., one of the first delayed signal Sd+ and the second delayed signal Sd− in this embodiment) of the quartz crystal resonator 120.

The compensation capacitor 130 is coupled between another output of the differential delay circuit 110 and an output of the quartz crystal resonator 120. In some embodiments, parasitic capacitance may exist between the input terminal and the output terminal of the quartz crystal resonator 120, thereby causing non-filtered high-frequency noise components to be coupled directly from the input terminal of the quartz crystal resonator 120 to the frequency signal Fout outputted by the quartz crystal resonator 120. With the presence of the compensation capacitor 130, the high-frequency noise components in the frequency signal Fout can be effectively suppressed.

The oscillator 140 is arranged to operably generate an oscillating signal under control of a control signal CTL.

The frequency divider 150 is coupled with the oscillator 140 and the differential delay circuit 110. The frequency divider 150 is arranged to operably conduct a frequency-dividing operation on the oscillating signal transmitted from the oscillator 140 to generate the input signal of the differential delay circuit 110. In other words, the input signal of the differential delay circuit 110 in this embodiment has a frequency lower than the oscillating signal generated by the oscillator 140.

The feedback control circuit 160 is coupled with the output of the quartz crystal resonator 120 and an input of the oscillator 140. The feedback control circuit 160 is arranged to operably generate the control signal CTL according to the frequency signal Fout, so as to control the oscillator 140 to adjust the frequency and/or phase of the resulting oscillating signal. In this way, low-frequency noise components in the frequency signal Fout can be effectively eliminated and the frequency of the frequency signal Fout can be stabilized at a desirable value.

The delay control circuit 170 is coupled with the differential delay circuit 110, and arranged to operably control a phase delay amount of the differential delay circuit 110 to thereby control the phases of the first delayed signal Sd+ and the second delayed signal Sd−.

In the embodiment of FIG. 1, the delay control circuit 170 is also coupled with the feedback control circuit 160 and controls the phase delay amount of the differential delay circuit 110 based on the control signal CTL. But this is merely an embodiment, rather than a restriction to the practical implementations. For example, the delay control circuit 170 may be configured to control the phase delay amount of the differential delay circuit 110 under control of other circuits (not shown).

The first digital phase detector 180 is coupled with the output of the oscillator 140, and arranged to operably compare a phase difference between a reference signal Sref and the oscillating signal generated by the oscillator 140.

The first digital loop filter 190 is coupled with the frequency divider 150 and the first digital phase detector 180. The first digital loop filter 190 is arranged to operably control the frequency-dividing operations of the frequency divider 150 according to a comparison result of the first digital phase detector 180.

In this situation, the divisor of the frequency divider 150 is programmable by adjusting the frequency or phase of the reference signal Sref or by modifying the parameters of the first digital loop filter 190.

In the embodiment of FIG. 1, the input signal of the differential delay circuit 110 is a pair of differential input signals Sin+ and Sin−, and the oscillating signal generated by the oscillator 140 is a pair of differential oscillating signals Fosc+ and Fosc−.

In practice, the differential delay circuit 110 may be realized with a voltage-controlled delay circuit or a digital-controlled delay circuit. In some embodiments where the phase delay amount of the differential delay circuit 110 is fixed, the differential delay circuit 110 may be realized with a single inverter or a certain number of inverters in series connection.

The quartz crystal resonator 120 may be realized by various piezoelectric materials, such as ceramic resonator and aluminum nitride (AlN).

The oscillator 140 may be realized with various circuits capable of generating a periodic signal having a certain frequency. For example, the oscillator 140 may be realized with a LC oscillator, a ring oscillator, a film bulk acoustic resonator (FBAR), a crystal oscillator, or an appropriate micro electro mechanical system (MEMS).

The frequency divider 150 may be realized with various circuits capable of dividing the frequency of the oscillating signal to generate a signal having a relatively-lower frequency to be the input signal of the differential delay circuit 110. For example, the frequency divider 150 may be realized with an integer-N frequency divider, a fractional-N frequency divider, a digital phased-locked loop (PLL) circuit, an analog PLL circuit, or a hybrid PLL circuit. In operations, the frequency divider 150 may divide the frequency of the oscillating signal by a predetermined fixed divisor or by a programmable divisor.

Different functional blocks of the frequency generating circuit 100 may be realized with separate circuits, or may be integrated into a single circuit chip.

As described previously, the frequency of the frequency signal Fout is determined by the phase difference between the output signal and the input signal of the quartz crystal resonator 120. Therefore, the frequency of the frequency signal Fout can be adjusted to a desirable value by adjusting the phase difference between the output signal and the input signal of the quartz crystal resonator 120. This means that the frequency of the frequency signal Fout can be adjusted to a desirable value by adjusting the phase of the input signal (i.e., one of the first delayed signal Sd+ and the second delayed signal Sd− in this embodiment) of the quartz crystal resonator 120, instead of adjusting the magnitude of the input current of the quartz crystal resonator 120.

For example, the differential delay circuit 110 may adjust the phase delay amount of its input signal to adjust the phase of the first delayed signal Sd+ and the second delayed signal Sd−. In another example, the frequency divider 150 may adjust the frequency or phase of the input signal of the differential delay circuit 110, so as to indirectly adjust the phase of the first delayed signal Sd+ and the second delayed signal Sd−. In yet another example, the oscillator 140 may adjust the frequency or phase of the oscillating signal under control of the control signal CTL, so as to indirectly adjust the phase of the first delayed signal Sd+ and the second delayed signal Sd−.

In the frequency generating circuit 100, the feedback control circuit 160 functions as a phase adjusting circuit for controlling the phase difference between the frequency signal Fout and the input signal of the quartz crystal resonator 120. For example, the feedback control circuit 160 may utilize the control signal CTL to control the oscillator 140 to adjust the frequency or phase of the oscillating signal, so as to indirectly adjust the phase of the first delayed signal Sd+ or the second delayed signal Sd− to be inputted into the quartz crystal resonator 120. As a result, the phase difference between the output signal and the input signal of the quartz crystal resonator 120 can be manipulated to a desired value accordingly.

In another aspect, the feedback control circuit 160 also functions as a noise filtering circuit or a noise suppression circuit for reducing the noise components in the frequency signal Fout by adopting a feedback control mechanism. Therefore, there is no need to reduce the noise level of the frequency signal Fout by increasing the current to be injected into the quartz crystal resonator 120. As a result, the input current of the quartz crystal resonator 120 can be configured as low as possible to reduce power consumption and to improve the reliability of the quartz crystal resonator 120.

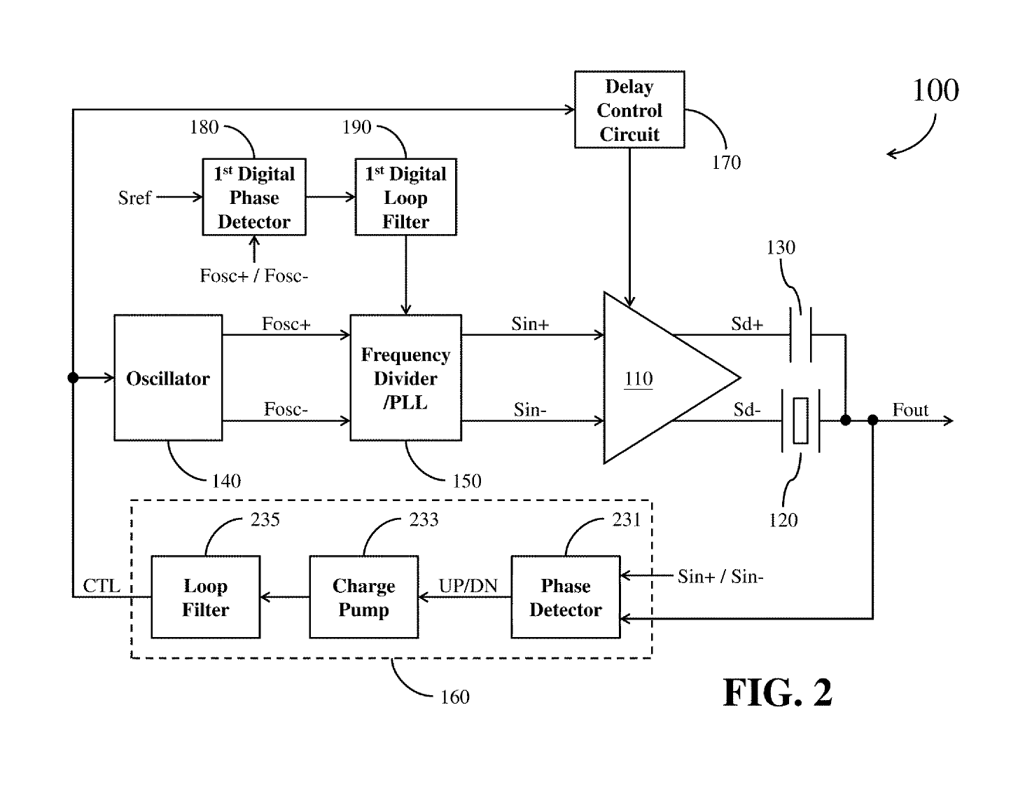

Please refer to FIG. 2, which shows a simplified functional block diagram of the feedback control circuit 160 according to a first embodiment of the present disclosure. In the embodiment of FIG. 2, the feedback control circuit 160 comprises a phase detector 231, a charge pump 233, and a loop filter 235.

The phase detector 231 is coupled with the output of the quartz crystal resonator 120 and an input of the differential delay circuit 110. The phase detector 231 is arranged to operably compare a phase difference between the frequency signal Fout and one of the differential input signals Sin+ and Sin−. The charge pump 233 is coupled with an output of the phase detector 231, and arranged to operably generate an output voltage according to a detection result of the phase detector 231. The loop filter 235 is coupled with an output of the charge pump 233 and the input of the oscillator 140, and arranged to operably reduce noise in the output voltage of the charge pump 233 to generate the control signal CTL.

For example, the phase detector 231 may generate a up signal UP or a down signal DN to indicate the comparison result of the input signal of the differential delay circuit 110 and the frequency signal Fout. In this situation, the charge pump 233 conducts a charging or discharging operation in response to the up signal UP or the down signal DN. The loop filter 235 may performs a low-pass filtering operation on the output signal of the charge pump 233 to generate the control signal CTL.

In practice, the phase detector 231 may be realized with a phase and frequency detector, a bang-bang phase detector, or a digital phase detector. In some embodiments where the output frequency of the oscillator 140 is controlled by the input voltage of the oscillator 140, the loop filter 235 may generate the control signal CTL in the format of a single-ended voltage signal or a pair of differential voltage signals.

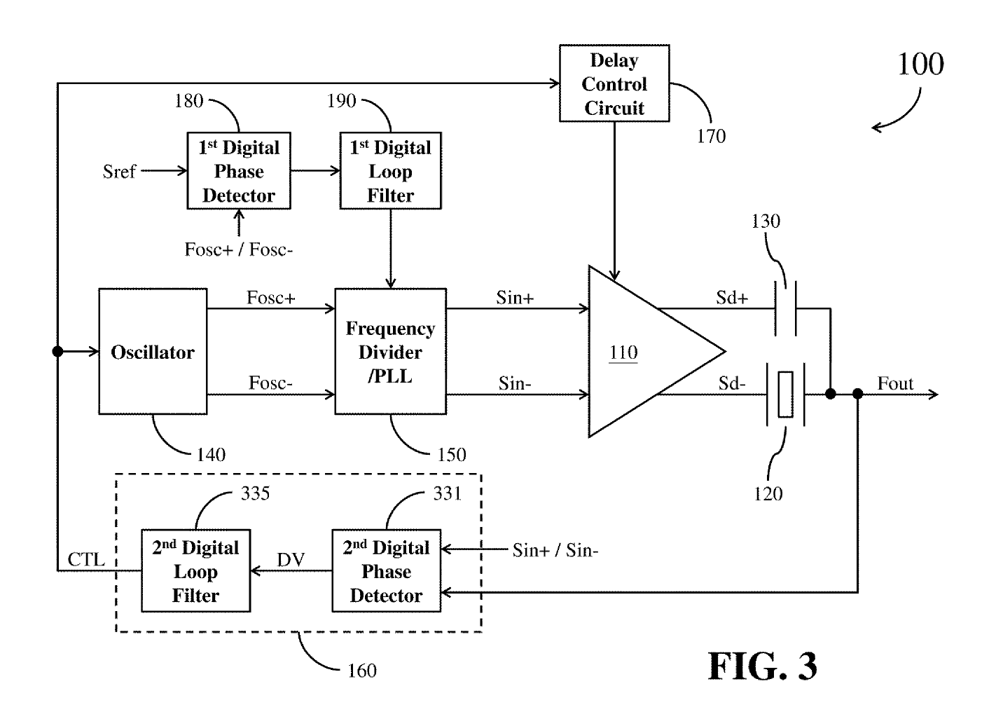

Please refer to FIG. 3, which shows a simplified functional block diagram of the feedback control circuit 160 according to a second embodiment of the present disclosure. In the embodiment of FIG. 3, the feedback control circuit 160 comprises a second digital phase detector 331 and a second digital loop filter 335.

The second digital phase detector 331 is coupled with the output of the quartz crystal resonator 120 and an input of the differential delay circuit 110. The second digital phase detector 331 is arranged to operably compare a phase difference between the frequency signal Fout and the input signal of the differential delay circuit 110 to generate a digital control value DV.

The second digital loop filter 335 is coupled with an output of the second digital phase detector 331 and the input of the oscillator 140, and arranged to operably generate the control signal CTL according to the digital control value DV.

That is, the feedback control circuit 160 in FIG. 3 is realized using an all-digital approach.

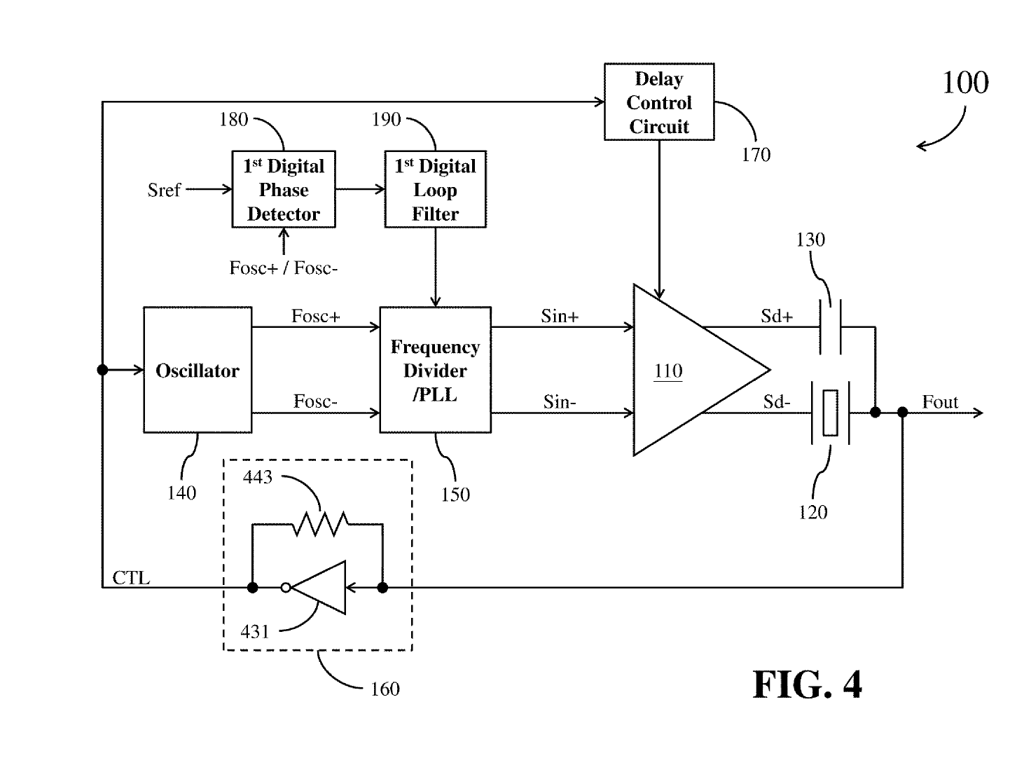

Please refer to FIG. 4, which shows a simplified functional block diagram of the feedback control circuit 160 according to a third embodiment of the present disclosure. In the embodiment of FIG. 4, the feedback control circuit 160 comprises an inverter circuit 431 and a resistor 433.

The inverter circuit 431 is coupled between the output of the quartz crystal resonator 120 and the input of the oscillator 140. The resistor 433 is coupled with the inverter circuit 431 to form a buffer circuit for generating the control signal CTL based on the frequency signal Fout.

In other words, the feedback control circuit 160 in the embodiment of FIG. 4 is able to conduct the feedback control operation based on merely the frequency signal Fout.

It can be appreciated from the foregoing descriptions that the high-frequency noise components in the frequency signal Fout can be suppressed by the compensation capacitor 130 while the low-frequency noise components in the frequency signal Fout can be filtered out due to the feedback control operation conducted by the feedback control circuit 160. Thus, there is no need to increase the current to be injected into the quartz crystal resonator 120 for reducing the noise caused by the quartz crystal resonator 120. As a result, the traditional trade-off between the reliability of the quartz crystal resonator and the noise level of the signal generated by the quartz crystal resonator no longer exists due to the use of the compensation capacitor 130 and the feedback control circuit 160. This means that the noise level of the frequency signal Fout can be effectively reduced while maintaining the input current of the quartz crystal resonator 120 at a low level.

Accordingly, the quartz crystal resonator 120 can operate with small input current, and thus the frequency generating circuit 100 is very suitable for low power consumption applications.

In addition, as described previously, the frequency of the frequency signal Fout is determined by the phase difference between the output signal and the input signal of the quartz crystal resonator 120, and can be adjusted to a desirable value by adjusting the phase difference between the output signal and the input signal of the quartz crystal resonator 120.

In other words, the frequency tuning range, i.e., the pulling range, of the frequency signal Fout is independent from the parasitic capacitance of the quartz crystal resonator 120. This means that the frequency tuning range of the frequency generating circuit 100 is no longer restricted by the material property of the quartz crystal resonator 120. Therefore, the pulling range of the frequency generating circuit 100 can be increased by adopting a normal quartz crystal resonator, instead of a high-end quartz crystal resonator. As a result, the overall hardware cost of the frequency generating circuit 100 can be reduced.

In the previous embodiments, some signals are realized in the differential format, but this is merely an exemplary embodiment rather than a restriction to the practical implementations.

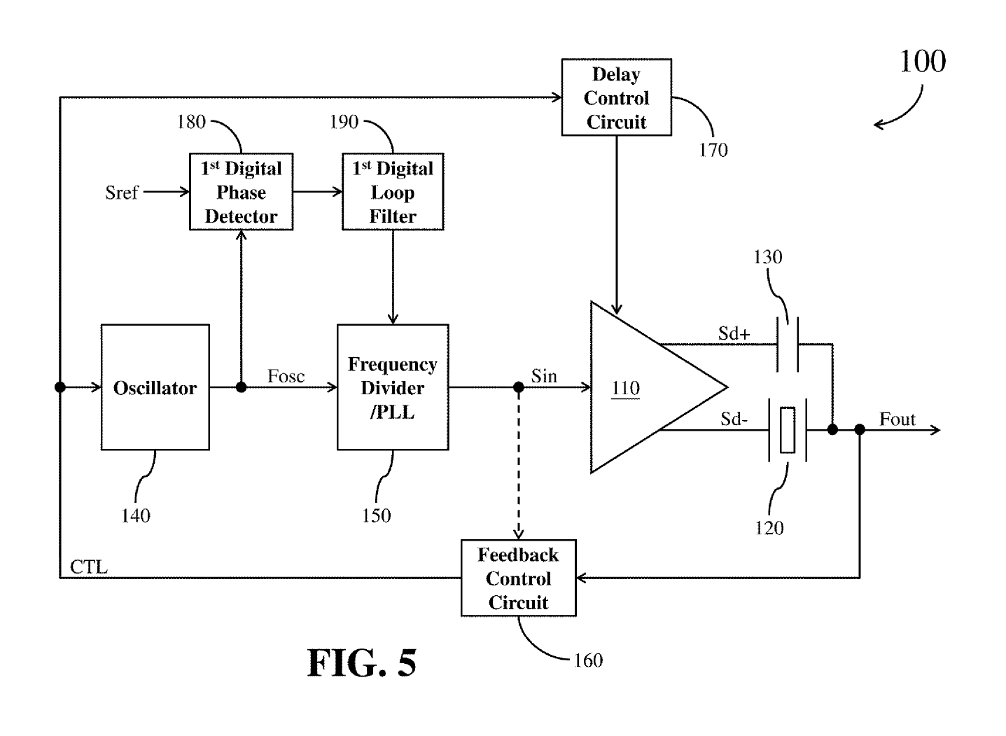

For example, FIG. 5 shows a simplified functional block diagram of the frequency generating circuit 100 according to a second embodiment of the present disclosure. In the embodiment of FIG. 5, the signal generated by the oscillating 140 is realized with a single-ended oscillating signal Fosc, while the signal generated by the frequency divider 150 is realized with a single-ended input signal Sin.

The foregoing descriptions regarding the implementations, connections, operations, and related advantages of other corresponding functional blocks in the embodiment of FIG. 1 are also applicable to the embodiment of FIG. 5. For the sake of brevity, those descriptions will not be repeated here.

Please note that the circuitry architecture illustrated in FIG. 1 or FIG. 5 is merely an exemplary embodiment rather than a restriction to the practical implementations. In practice, one or more functional blocks shown in FIG. 1 may be omitted to meet the requirements of different applications.

For example, in some embodiments where the divisor of the frequency divider 150 is fixed, the first digital phase detector 180 and the first digital loop filter 190 may be omitted.

In some embodiments, the frequency divider 150 may be omitted to further simplify the circuitry structure. In this situation, the oscillating signal (e.g., the signal Fosc, Fosc+, and/or Fosc−) may be utilized to be the input signal of the differential delay circuit 110.

In some embodiments where the phase delay amount of the differential delay circuit 110 is configured to be a fixed value, the delay control circuit 170 may be omitted.

In some embodiments where the low-frequency noise components in the frequency signal Fout is not a concern, both the oscillator 140 and feedback control circuit 160 may be omitted.

In some embodiments where the high-frequency noise components in the frequency signal Fout is not a concern, the compensation capacitor 130 may be omitted.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The term “couple” is intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The term “and/or” may comprise any and all combinations of one or more of the associated listed items. In addition, the singular forms “a,” “an,” and “the” herein are intended to comprise the plural forms as well, unless the context clearly indicates otherwise.

The term “voltage signal” used throughout the description and the claims may be expressed in the format of a current in implementations, and the term “current signal” used throughout the description and the claims may be expressed in the format of a voltage in implementations.

Other embodiments of the invention will be apparent to those skilled in the art from consideration of the specification and practice of the invention disclosed herein. It is intended that the specification and examples be considered as exemplary only, with a true scope and spirit of the invention indicated by the following claims.

What is claimed is:

1. A frequency generating circuit (100), comprising:
a differential delay circuit (110), arranged to operably delay an input signal (Sin; Sin+, Sin−) to generate a pair of differential delayed signals (Sd+, Sd−), wherein the pair of differential delayed signals (Sd+, Sd−) includes a first delayed signal (Sd+) and a second delayed signal (Sd−);
a quartz crystal resonator (120), coupled with one output of the differential delay circuit (110), arranged to operably conduct a band-pass filtering operation on one of the first and second delayed signals (Sd+, Sd−) to generate a frequency signal (Fout);
a compensation capacitor (130), coupled between another output of the differential delay circuit (110) and an output of the quartz crystal resonator (120), arranged to operably suppress noise in the frequency signal (Fout);
an oscillator (140) arranged to operably generate an oscillating signal (Fosc; Fosc+, Fosc−) under control of a control signal (CTL);
a frequency divider (150), coupled with the oscillator (140) and the differential delay circuit (110), arranged to operably conduct a frequency-dividing operation on the oscillating signal (Fosc; Fosc+, Fosc−) to generate the input signal (Sin; Sin+, Sin−); and
a feedback control circuit (160), coupled with the output of the quartz crystal resonator (120) and an input of the oscillator (140), arranged to operably generate the control signal (CTL) according to the frequency signal (Fout).

2. The frequency generating circuit (100) of claim 1, further comprising:
a first digital phase detector (180), coupled with an output of the oscillator (140), arranged to operably compare a phase difference between a reference signal (Sref) and the oscillating signal (Fosc; Fosc+; Fosc−); and
a first digital loop filter (190), coupled with the frequency divider (150) and the first digital phase detector (180), arranged to operably control the frequency divider (150) according to a comparison result of the first digital phase detector (180).

3. The frequency generating circuit (100) of claim 1, wherein the feedback control circuit (160) comprises:
a phase detector (231), coupled with the output of the quartz crystal resonator (120) and an input of the differential delay circuit (110), arranged to operably compare a phase difference between the frequency signal (Fout) and the input signal (Sin; Sin+; Sin−);
a charge pump (233), coupled with an output of the phase detector (231), arranged to operably generate an output voltage according to a detection result of the phase detector (231); and
a loop filter (235), coupled with an output of the charge pump (233) and the input of the oscillator (140), arranged to operably reduce noise in the output voltage of the charge pump (233) to generate the control signal (CTL).

4. The frequency generating circuit (100) of claim 1, wherein the feedback control circuit (160) comprises:
a second digital phase detector (331), coupled with the output of the quartz crystal resonator (120) and an input of the differential delay circuit (110), arranged to operably compare a phase difference between the frequency signal (Fout) and the input signal (Sin; Sin+; Sin−) to generate a digital control value (DV); and
a second digital loop filter (335), coupled with an output of the second digital phase detector (331) and the input of the oscillator (140), arranged to operably generate the control signal (CTL) according to the digital control value (DV).

5. The frequency generating circuit (100) of claim 1, wherein the feedback control circuit (160) comprises:
an inverter circuit (431), coupled between the output of the quartz crystal resonator (120) and the input of the oscillator (140); and
a resistor (433) coupled with the inverter circuit (431) to form a buffer circuit for generating the control signal (CTL) based on the frequency signal (Fout).

6. The frequency generating circuit (100) of claim 1, further comprising:
a delay control circuit (170), coupled with the differential delay circuit (110), arranged to operably control a phase delay amount of the differential delay circuit (110).

7. The frequency generating circuit (100) of claim 6, wherein the delay control circuit (170) is coupled with the feedback control circuit (160) and controls the phase delay amount of the differential delay circuit (110) based on the control signal (CTL).

8. A frequency generating circuit (100), comprising:
a differential delay circuit (110), arranged to operably delay an input signal (Sin; Sin+, Sin−) to generate a pair of differential delayed signals (Sd+, Sd−), wherein the pair of differential delayed signals (Sd+, Sd−) includes a first delayed signal (Sd+) and a second delayed signal (Sd−);
a quartz crystal resonator (120), coupled with one output of the differential delay circuit (110), arranged to operably conduct a band-pass filtering operation on one of the first and second delayed signals (Sd+, Sd−) to generate a frequency signal (Fout);
a compensation capacitor (130), coupled between another output of the differential delay circuit (110) and an output of the quartz crystal resonator (120), arranged to operably suppress noise in the frequency signal (Fout);
an oscillator (140), coupled with the differential delay circuit (110), arranged to operably generate an oscillating signal (Fosc; Fosc+, Fosc−) to be the input signal (Sin; Sin+, Sin−) under control of a control signal (CTL); and
a feedback control circuit (160), coupled with the output of the quartz crystal resonator (120) and an input of the oscillator (140), arranged to operably generate the control signal (CTL) according to the frequency signal (Fout).

9. The frequency generating circuit (100) of claim 8, wherein the feedback control circuit (160) comprises:
a phase detector (231), coupled with the output of the quartz crystal resonator (120) and an input of the differential delay circuit (110), arranged to operably compare a phase difference between the frequency signal (Fout) and the input signal (Sin; Sin+; Sin−);
a charge pump (233), coupled with an output of the phase detector (231), arranged to operably generate an output voltage according to a detection result of the phase detector (231); and
a loop filter (235), coupled with an output of the charge pump (233) and the input of the oscillator (140), arranged to operably reduce noise in the output voltage of the charge pump (233) to generate the control signal (CTL).

10. The frequency generating circuit (100) of claim 8, wherein the feedback control circuit (160) comprises:
a second digital phase detector (331), coupled with the output of the quartz crystal resonator (120) and an input of the differential delay circuit (110), arranged to operably compare a phase difference between the frequency signal (Fout) and the input signal (Sin; Sin+; Sin−) to generate a digital control value (DV); and
a second digital loop filter (335), coupled with an output of the second digital phase detector (331) and the input of the oscillator (140), arranged to operably generate the control signal (CTL) according to the digital control value (DV).

11. The frequency generating circuit (100) of claim 8, wherein the feedback control circuit (160) comprises:
an inverter circuit (431), coupled between the output of the quartz crystal resonator (120) and the input of the oscillator (140); and
a resistor (433) coupled with the inverter circuit (431) to form a buffer circuit for generating the control signal (CTL) based on the frequency signal (Fout).

12. The frequency generating circuit (100) of claim 8, further comprising:
a delay control circuit (170), coupled with the differential delay circuit (110), arranged to operably control a phase delay amount of the differential delay circuit (110).

13. The frequency generating circuit (100) of claim 12, wherein the delay control circuit (170) is coupled with the feedback control circuit (160) and controls the phase delay amount of the differential delay circuit (110) based on the control signal (CTL).

14. A frequency generating circuit (100), comprising:
a differential delay circuit (110), arranged to operably delay an input signal (Sin; Sin+, Sin−) to generate a pair of differential delayed signals (Sd+, Sd−), wherein the pair of differential delayed signals (Sd+, Sd−) includes a first delayed signal (Sd+) and a second delayed signal (Sd−);
a quartz crystal resonator (120), coupled with one output of the differential delay circuit (110), arranged to operably conduct a band-pass filtering operation on one of the first and second delayed signals (Sd+, Sd−) to generate a frequency signal (Fout); and
a compensation capacitor (130), coupled between another output of the differential delay circuit (110) and an output of the quartz crystal resonator (120), arranged to operably suppress noise in the frequency signal (Fout).

15. The frequency generating circuit (100) of claim 14, further comprising:
a delay control circuit (170), coupled with the differential delay circuit (110), arranged to operably control a phase delay amount of the differential delay circuit (110).
